(19) United States
(12) Patent Application Publication
(10) Pub. No.: US 2024/0250153 A1
(43) Pub. Date: Jul. 25, 2024

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kun-Yi LIN, Hsinchu (TW); Tai-Jung KUO, Hsinchu (TW); Yunn-Shiuan LIU, Taipei (TW); Zhen-Cheng WU, Hsinchu (TW); Chi On CHUI, Hsinchu (TW)

(21) Appl. No.: 18/099,405

(22) Filed: Jan. 20, 2023

(51) Int. Cl. H01L 29/66; H01L 21/768; H01L 21/8234; H01L 27/088; H01L 29/40; H01L 29/423; H01L 29/78

(52) U.S. Cl. CPC H01L 29/66795; H01L 21/76856; H01L 21/76876; H01L 21/823431; H01L 21/823481; H01L 27/0886; H01L 29/401; H01L 29/4232; H01L 29/7851

(57) ABSTRACT

A semiconductor device structure, along with methods of forming such, are described. The structure includes a gate electrode disposed over a semiconductor substrate and a gate cut-fill structure disposed in the gate electrode to separate the gate electrode into two portions. The gate cut-fill structure includes a first liner, a second liner disposed on the first liner, and a dielectric material disposed on the second liner. The dielectric material has a “V” shaped cross-section.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A-B, 4A-D, 5A-C, 6A-C, 7A-C, and 8A-C are various views of respective intermediate structures at intermediate stages in an example process of forming a semiconductor device structure including one or more FinFETs, in accordance with some embodiments.

FIGS. 9A-9E are cross-sectional views at various instances of processing corresponding to cross-section A-A in FIG. 4D, in accordance with some embodiments.

FIGS. 10A-10C are various views of one the intermediate structure at one of intermediate stages in the example process of forming the semiconductor device structure, in accordance with some embodiments.

FIGS. 11A-11D are cross-sectional views at various instances of processing corresponding to cross-section A-A in FIG. 4D, in accordance with alternative embodiments.

FIGS. 12A-12E are cross-sectional views at various instances of processing corresponding to cross-section A-A in FIG. 4D, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Methods of cutting fins in a semiconductor device structure, such as Fin Field-Effect Transistors (FinFETs), are described herein. Generally, a fin cut process is performed after a dummy gate or a replacement gate structure has been formed and cut. The fin cut process can include removing one or more fins, the isolation region disposed around the fins, and the portion of a semiconductor substrate located under the isolation region. By removing the portion of the semiconductor substrate located under the isolation region around the one or more fins, current leakage via the portion of the semiconductor substrate is substantially reduced.

Example embodiments described herein are described in the context of FinFETs. Implementations of some aspects of the present disclosure may be used in other processes and/or in other devices. Some variations of the example methods and structures are described. A person having ordinary skill in the art will readily understand other modifications that may be made that are contemplated within the scope of other embodiments. Although method embodiments may be described in a particular order, various other method embodiments may be performed in any logical order and may include fewer or more steps than what is described herein.

In some instances, in the described embodiments, various losses, e.g., in height, to the illustrated structures may occur during processing. These losses may not be expressly shown in the figures or described herein, but a person having ordinary skill in the art will readily understand how such losses may occur. Such losses may occur as a result of a planarization process such as a chemical mechanical polish (CMP), an etch process when, for example, the structure realizing the loss is not the primary target of the etching, and other processes.

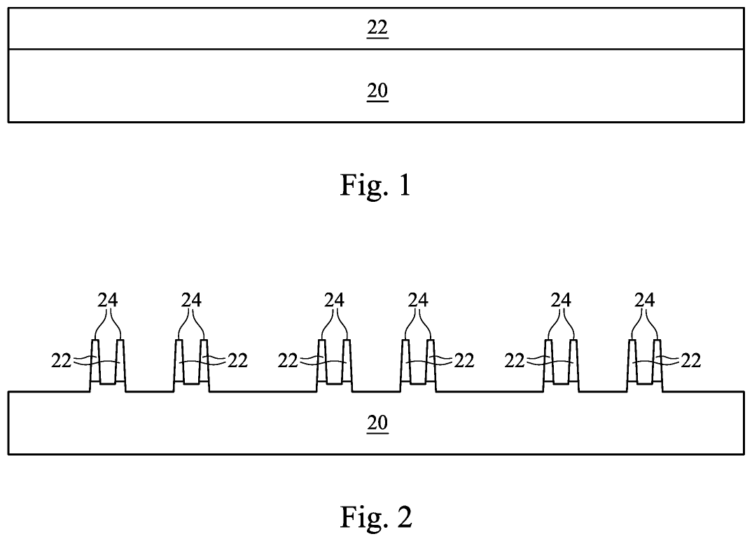

FIGS. 1, 2, 3A-B, 4A-D, and 5A-C through 8A-C are various views of respective intermediate structures during intermediate stages in an example process of forming a semiconductor device structure including one or more FinFETs, in accordance with some embodiments. FIG. 1 illustrates, in a cross-sectional view, a semiconductor substrate 20 with a stressed semiconductor layer 22 formed thereover. The semiconductor substrate 20 maybe or include a bulk semiconductor substrate, a semiconductor-on-insulator (SOI) substrate, or the like, which may be doped (e.g., with a p-type or an n-type dopant) or undoped. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the semiconductor substrate may include an elemental semiconductor such as silicon (Si) and germanium (Ge); a compound semiconductor including silicon carbide, gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or a combination thereof.

The stressed semiconductor layer 22 can have a compressive stress or a tensile stress. In some examples, the stressed semiconductor layer 22 is stressed as a result of heteroepitaxial growth on the semiconductor substrate 20. For example, heteroepitaxial growth generally includes epitaxially growing a grown material having a natural lattice constant that is different from the lattice constant of the substrate material at the surface on which the grown material is epitaxially grown. Pseudomorphically growing the grown material on the substrate material can result in the grown material having a stress. If the natural lattice constant of the grown material is greater than the lattice constant of the substrate material, the stress in the grown material can be compressive, and if the natural lattice constant of the grown material is less than the lattice constant of the substrate material, the stress in the grown material can be tensile. For example, pseudomorphically growing SiGe on relaxed silicon can result in the SiGe having a compressive stress, and pseudomorphically growing SiC on relaxed silicon can result in the SiC having a tensile stress.

The stressed semiconductor layer 22 can be or include silicon, silicon germanium (Si₁₋ₓGeₓ, where x can be between approximately 0 and 100), silicon carbide, pure or substantially pure germanium, a III-V compound semiconductor, a II-VI compound semiconductor, or the like. For example, materials for forming a III-V compound semiconductor include InAs, AlAs, GaAs, InP, GaN, InGaAs, InAlAs, GaSb, AlSb, AlP, GaP, and the like. Further, the stressed semiconductor layer 22 can be epitaxially grown using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof on the semiconductor substrate 20. A thickness of the stressed semiconductor layer 22 can be in a range from about 30 nm to about 50 nm.

FIG. 2 illustrates, in a cross-sectional view, the formation of fins 24 in the stressed semiconductor layer 22 and/or semiconductor substrate 20. In some examples, a mask (e.g., a hard mask) is used in forming the fins 24. For example, one or more mask layers are deposited over the stressed semiconductor layer 22, and the one or more mask layers are then patterned into the mask. In some examples, the one or more mask layers may include or be silicon nitride, silicon oxynitride, silicon carbide, silicon carbon nitride, the like, or a combination thereof, and may be deposited by chemical vapor deposition (CVD), physical vapor deposition (PVD), atomic layer deposition (ALD), or another deposition technique. The one or more mask layers may be patterned using photolithography. For example, a photo resist can be formed on the one or more mask layers, such as by using spin-on coating, and patterned by exposing the photo resist to light using an appropriate photomask. Exposed or unexposed portions of the photo resist may then be removed depending on whether a positive or negative resist is used. The pattern of the photo resist may then be transferred to the one or more mask layers, such as by using a suitable etch process, which forms the mask. The etch process may include a reactive ion etch (RIE), neutral beam etch (NBE), inductive coupled plasma (ICP) etch, the like, or a combination thereof. The etch process may be anisotropic. Subsequently, the photo resist is removed in an ashing or wet strip processes, for example.

Using the mask, the stressed semiconductor layer 22 and/or semiconductor substrate 20 maybe etched such that trenches are formed between neighboring pairs of fins 24 and such that the fins 24 protrude from the semiconductor substrate 20. In some embodiments, each fin 24 has a height ranging from about 115 nm to about 120 nm. The etch process may include a RIE, NBE, ICP etch, the like, or a combination thereof. The etch process may be anisotropic. The trenches may be formed to a depth in a range from about 80 nm to about 150 nm from the top surface of the stressed semiconductor layer 22. In some embodiments, the trench between a pair of fins 24 maybe substantially shallower than the trench between neighboring pairs of fins 24 due to the loading effect, as shown in FIG. 2. In some embodiments where the trenches have different depths, the different depths may not be explicitly illustrated.

Although examples described herein are in the context of stress engineering for the fins 24 (e.g., the fins 24 include respective portions of the stressed semiconductor layer 22), other examples may not implement such stress engineering. For example, the fins 24 maybe formed from a bulk semiconductor substrate (e.g., semiconductor substrate 20) without a stressed semiconductor layer. Also, the stressed semiconductor layer 22 maybe omitted from subsequent figures; this is for clarity of the figures. In some embodiments where such a stress semiconductor layer is implemented for stress engineering, the stressed semiconductor layer 22 maybe present as part of the fins 24 even if not explicitly illustrated; and in some embodiments where such a stress semiconductor layer is not implemented for stress engineering, the fins 24 maybe formed from the semiconductor substrate 20.

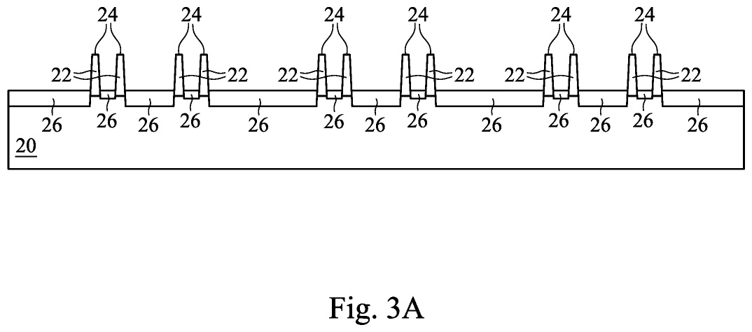

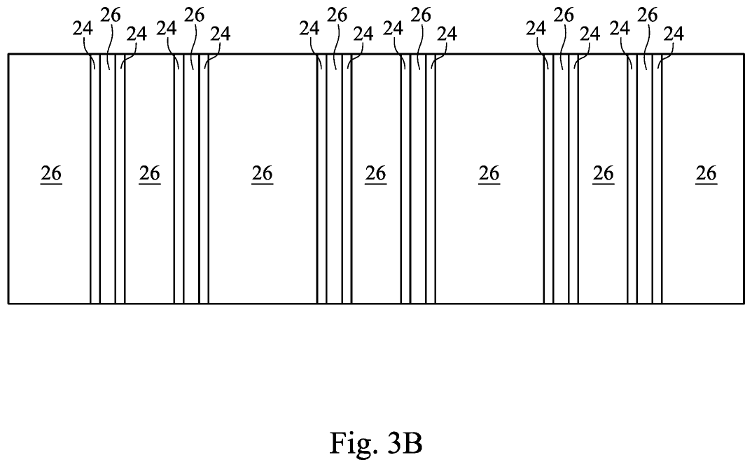

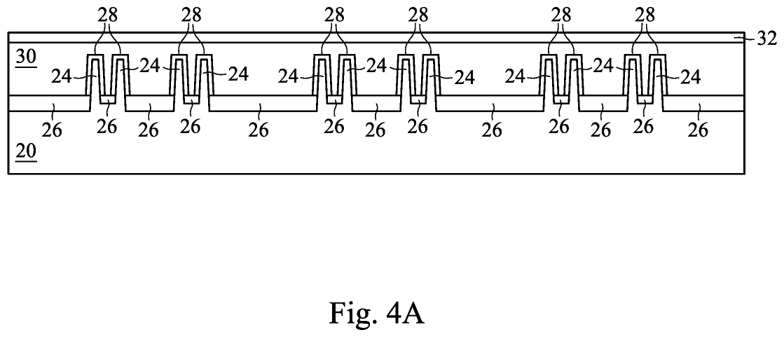

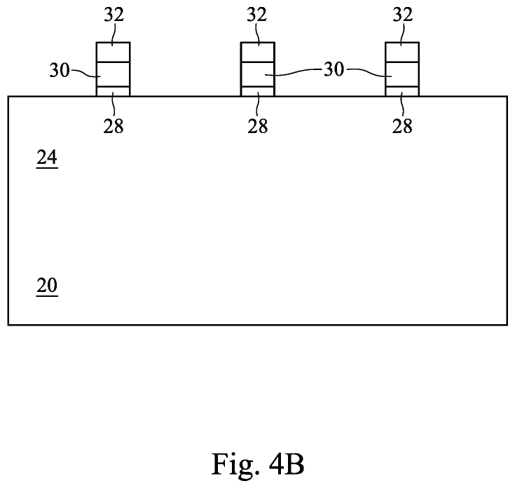

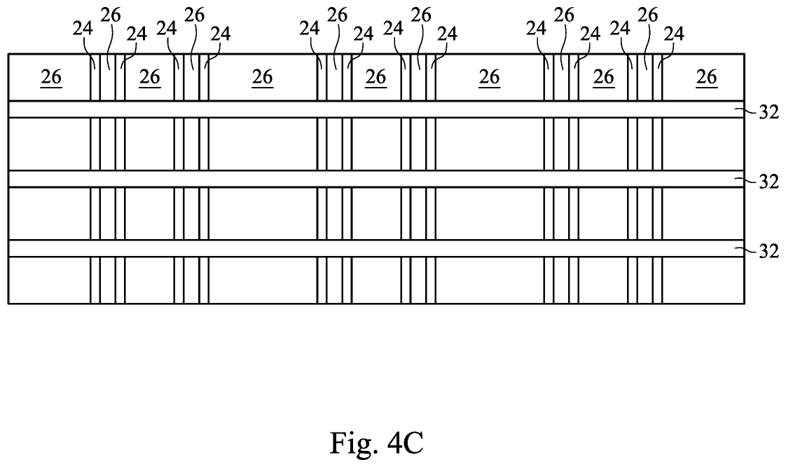

FIGS. 3A and 3B illustrate, in a cross-sectional view and top view, respectively, the formation of isolation regions 26, each in a corresponding trench. The isolation regions 26 may include or be an insulating material, such as an oxide (such as silicon oxide), a nitride, the like, or a combination thereof, and the insulating material may be formed by a high density plasma CVD (HDP-CVD), a flowable CVD (FCVD) (e.g., a CVD-based material deposition in a remote plasma system and post curing to make it convert to another material, such as an oxide), the like, or a combination thereof. Other insulating materials formed by any acceptable process may be used. In the illustrated embodiment, the isolation regions 26 include silicon oxide that is formed by a FCVD process. A planarization process, such as a CMP, may remove any excess insulating material and any remaining mask (e.g., used to form the trenches and the fins 24) to form coplanar top surfaces of the insulating material and the fins 24. The insulating material may then be recessed to form the isolation regions 26. The insulating material is recessed such that the fins 24 protrude from between neighboring isolation regions 26, which may at least in part, thereby delineate the fins 24 as active areas on the semiconductor substrate 20. The insulating material may be recessed using an acceptable dry or wet etch process, such as one that is selective to the material of the insulating material. Further, top surfaces of the isolation regions 26 may have a flat surface as illustrated, a convex surface, a concave surface (such as dishing), or a combination thereof, which may result from an etch process. As illustrated in the top view of FIG. 3B, the fins 24 extend longitudinally across the semiconductor substrate 20. The fins 24 may have a height in a range from about 30 nm to about 50 nm from top surfaces of respective neighboring isolation regions 26. For example, the interface between the stressed semiconductor layer 22 and the semiconductor substrate 20 corresponding to each fin 24 can be below top surfaces of the isolation regions 26.

A person having ordinary skill in the art will readily understand that the processes described with respect to FIGS. 1 through 3A-B are just examples of how fins 24 maybe formed. In other embodiments, a dielectric layer can be formed over a top surface of the semiconductor substrate 20; trenches can be etched through the dielectric layer; homoepitaxial structures can be epitaxially grown in the trenches (e.g., without stress engineering); and the dielectric layer can be recessed such that the homoepitaxial structures protrude from the dielectric layer to form fins. In still other embodiments, heteroepitaxial structures can be used for the fins. For example, the fins 24 can be recessed (e.g., after planarizing the insulating material of the isolation regions 26 and before recessing the insulating material), and a material different from the fins may be epitaxially grown in their place. In an even further embodiment, a dielectric layer can be formed over a top surface of the semiconductor substrate 20; trenches can be etched through the dielectric layer; heteroepitaxial structures can be epitaxially grown in the trenches using a material different from the semiconductor substrate 20 (e.g., with stress engineering); and the dielectric layer can be recessed such that the heteroepitaxial structures protrude from the dielectric layer to form fins. In some embodiments where homoepitaxial or heteroepitaxial structures are epitaxially grown, the grown materials may be in situ doped during growth, which may obviate prior implanting of the fins although in situ and implantation doping may be used together. Still further, it may be advantageous to epitaxially grow a material for an n-type device different from the material in for a p-type device.

FIGS. 4A, 4B, 4C and 4D illustrate the formation of dummy gate stacks on the fins 24. FIGS. 4A and 4B illustrate cross-sectional views; FIG. 4C illustrates a top view; and FIG. 4D illustrates a perspective view. FIG. 4D illustrates cross-sections A-A and B-B. FIGS. 1, 2, 3A, 4A, and the following figures (up to FIGS. 8A-C) ending with an “A” designation illustrate cross-sectional views at various instances of processing corresponding to cross-section A-A, and FIG. 4B and the following figures (up to FIGS. 8A-C) ending with a “B” designation illustrate cross-sectional views at various instances of processing corresponding to cross-section B-B. In some figures, some reference numbers of components or features illustrated therein may be omitted to avoid obscuring other components or features; this is for ease of depicting the figures.

The dummy gate stacks are over and extend laterally perpendicularly to the fins 24. Each dummy gate stack, or more generally, gate structure, includes one or more interfacial dielectrics 28, a dummy gate 30, and a mask 32. The one or more interfacial dielectrics 28, dummy gates 30, and mask 32 for the dummy gate stacks may be formed by sequentially forming respective layers, and then patterning those layers into the dummy gate stacks. For example, a layer for the one or more interfacial dielectrics 28 may include or be silicon oxide, silicon nitride, the like, or multilayers thereof, and may be thermally and/or chemically grown on the fins 24, as illustrated, or conformally deposited, such as by plasma-enhanced CVD (PECVD), ALD, or another deposition technique. A layer for the dummy gates 30 may include or be silicon (e.g., polysilicon) or another material deposited by CVD, PVD, or another deposition technique. A layer for the mask 32 may include or be silicon nitride, silicon oxynitride, silicon carbon nitride, the like, or a combination thereof, deposited by CVD, PVD, ALD, or another deposition technique. The layers for the mask 32, dummy gates 30, and one or more interfacial dielectrics 28 may then be patterned, for example, using photolithography and one or more etch processes, like described above, to form the mask 32, dummy gate 30, and one or more interfacial dielectrics 28 for each dummy gate stack.

In some embodiments, after forming the dummy gate stacks, lightly doped drain (LDD) regions (not specifically illustrated) may be formed in the fins 24. For example, dopants may be implanted into the fins 24 using the dummy gate stacks as masks. Example dopants for the LDD regions can include or be, for example, boron for a p-type device and phosphorus or arsenic for an n-type device, although other dopants may be used. The LDD regions may have a dopant concentration in a range from about 10¹⁵ cm⁻³ to about 10¹⁷ cm⁻³.

The cross-section A-A is along a gate stack through which a cut will be made in subsequent figures and description. The cross-section B-B is along a fin 24 (e.g., along a channel direction in the fin 24) through which a cut will be made in subsequent figures and description. Cross-sections A-A and B-B are perpendicular to each other.

FIGS. 5A, 5B, and 5C illustrate the formation of gate spacers 34. Gate spacers 34 are formed along sidewalls of the dummy gate stacks (e.g., sidewalls of the one or more interfacial dielectrics 28, dummy gates 30, and masks 32) and over the fins 24. Additionally, residual gate spacers 34 maybe formed along exposed sidewalls of the fins 24, as illustrated in the figures. The gate spacers 34 maybe formed by conformally depositing one or more layers for the gate spacers 34 and anisotropically etching the one or more layers, for example. The one or more layers for the gate spacers 34 may include or be silicon nitride, silicon oxynitride, silicon carbon nitride, silicon oxycarbide, the like, multi-layers thereof, or a combination thereof, and the etch process can include a RIE, NBE, or another etch process.

Epitaxy source/drain regions 36 are then formed in the fins 24. Recesses for epitaxy source/drain regions 36 are formed in the fins 24 on opposing sides of the dummy gate stacks. The recessing can be by an etch process. The etch process can be isotropic or anisotropic, or further, may be selective with respect to one or more crystalline planes of the stressed semiconductor layer 22 and/or semiconductor substrate 20. Hence, the recesses can have various cross-sectional profiles based on the etch process implemented. The etch process may be a dry etch process, such as a RIE, NBE, or the like, or a wet etch process, such as using tetramethyalammonium hydroxide (TMAH), ammonium hydroxide (NH₄OH), or another etchant. The recesses may extend to a depth in a range from about 0 nm to about 80 nm from respective top surfaces of the fins 24 into the fins 24. For example, the recesses may in some instances, not extend below a level of top surfaces of neighboring isolation regions 26 and/or below the interface between the stressed semiconductor layer 22 and the semiconductor substrate 20; although in other instances, the recesses may extend below a level of top surfaces of neighboring isolation regions 26 and/or the interface.

Epitaxy source/drain regions 36 are formed in the recesses in the fins 24. The epitaxy source/drain regions 36 may include or be silicon germanium (Si₁₋ₓGeₓ, where x can be between approximately 0 and 100), silicon carbide, silicon phosphorus, silicon carbon phosphorus, pure or substantially pure germanium, a III-V compound semiconductor, a II-VI compound semiconductor, or the like. For example, materials for forming a III-V compound semiconductor include InAs, AlAs, GaAs, InP, GaN, InGaAs, InAlAs, GaSb, AlSb, AlP, GaP, and the like. The epitaxy source/drain regions 36 maybe formed in the recesses by epitaxially growing a material in the recesses, such as by MOCVD, MBE, LPE, VPE, SEG, the like, or a combination thereof. Due to blocking by the isolation regions 26 and/or residual gate spacers 34 depending on the depth of the recess in which the epitaxy source/drain region 36 is formed, epitaxy source/drain regions 36 maybe first grown vertically in recesses, during which time the epitaxy source/drain regions 36 do not grow horizontally. After the recesses within the isolation regions 26 and/or residual gate spacers 34 are fully filled, the epitaxy source/drain regions 36 may grow both vertically and horizontally to form facets, which may correspond to crystalline planes of the semiconductor substrate 20. Epitaxy source/drain regions 36 maybe raised in relation to the fin 24, as illustrated by dashed lines in FIG. 5B. In some examples, different materials are used for epitaxy source/drain regions for p-type devices and n-type devices. Appropriate masking during the recessing or epitaxial growth may permit different materials to be used in different devices. In this disclosure, a source region and a drain region are interchangeably used, and the structures thereof are substantially the same. Furthermore, source/drain region(s) may refer to a source or a drain, individually or collectively dependent upon the context.

FIGS. 6A, 6B, and 6C illustrate the formation of a contact etch stop layer (CESL) 38 and an interlayer dielectric (ILD) 40. The CESL 38 maybe conformally deposited over the fins 24, dummy gate stacks, gate spacers 34, and isolation regions 26. The CESL 38 may include or be silicon nitride, silicon carbon nitride, silicon carbon oxide, carbon nitride, the like, or a combination thereof, and may be deposited by CVD, PECVD, ALD, or another deposition technique. The ILD 40 is deposited over the CESL 38. The ILD 40 may include or be silicon dioxide, a low-k dielectric material (e.g., a material having a dielectric constant lower than silicon dioxide), such as silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOxCy, Spin-On-Glass, Spin-On-Polymers, silicon carbon material, a compound thereof, a composite thereof, the like, or a combination thereof. The ILD 40 maybe deposited by spin-on, CVD, FCVD, PECVD, PVD, or another deposition technique.

The CESL 38 and ILD 40 are formed with top surfaces coplanar with top surfaces of the dummy gates 30. A planarization process, such as a CMP, may be performed to level the top surfaces of the ILD 40 and CESL 38 with the top surfaces of the dummy gates 30. The CMP may also remove the mask 32 (and, in some instances, upper portions of the gate spacers 34) on the dummy gates 30. Accordingly, top surfaces of the dummy gates 30 are exposed through the ILD 40 and CESL 38.

FIGS. 7A, 7B, and 7C illustrate the removal of the dummy gate stacks. The dummy gates 30 and one or more interfacial dielectrics 28 are removed, such as by one or more etch processes. The dummy gates 30 maybe removed by an etch process selective to the dummy gates 30, wherein the one or more interfacial dielectrics 28 act as ESLs, and subsequently, the one or more interfacial dielectrics 28 can be removed by a different etch process selective to the one or more interfacial dielectrics 28. The etch processes can be, for example, a RIE, NBE, a wet etch process, or another etch process. Recesses 42 are formed between gate spacers 34 where the dummy gate stacks are removed, and channel regions of the fins 24 are exposed through the recesses 42. In some embodiments, the interfacial dielectrics 28 are not removed.

FIGS. 8A, 8B, and 8C illustrate the formation of replacement gate structures in the recesses 42. The replacement gate structures each include a gate dielectric layer 44, one or more optional conformal layers 46, and a gate electrode 48.

The gate dielectric layer 44 is conformally deposited in the recesses 42 (e.g., on top surfaces of the isolation regions 26, sidewalls and top surfaces of the fins 24 (or the interfacial dielectrics 28 if not removed) along the channel regions, and sidewalls of the gate spacers 34) and on the top surfaces of the gate spacers 34, the CESL 38, and ILD 40. The gate dielectric layer 44 can be or include silicon oxide, silicon nitride, a high-k dielectric material, multilayers thereof, or other dielectric material. A high-k dielectric material may have a k value greater than about 7.0, and may include a metal oxide of or a metal silicate of hafnium (Hf), aluminum (Al), zirconium (Zr), lanthanum (La), magnesium (Mg), barium (Ba), titanium (Ti), lead (Pb), multilayers thereof, or a combination thereof. The gate dielectric layer 44 can be deposited by ALD, PECVD, MBD, or another deposition technique.

Then, the one or more optional conformal layers 46 can be conformally (and sequentially, if more than one) deposited on the gate dielectric layer 44. The one or more optional conformal layers 46 can include one or more work-function tuning layers. The one or more work-function tuning layer may include or be a nitride, silicon nitride, carbon nitride, aluminum nitride, aluminum oxide, and/or aluminum carbide of titanium and/or tantalum; a carbide of tungsten; cobalt; platinum; the like; or a combination thereof; and may be deposited by ALD, PECVD, MBD, or another deposition technique.

A layer for the gate electrodes 48 is formed over the gate dielectric layer 44 and, if implemented, the one or more optional conformal layers 46. The layer for the gate electrodes 48 can fill remaining recesses 42 where the dummy gate stacks were removed. The layer for the gate electrodes 48 maybe or include a metal-containing material such as tungsten, cobalt, aluminum, ruthenium, copper, multi-layers thereof, a combination thereof, or the like. The layer for the gate electrodes 48 can be deposited by ALD, PECVD, MBD, PVD, or another deposition technique.

Portions of the layer for the gate electrodes 48, one or more optional conformal layers 46, and gate dielectric layer 44 above the top surfaces of the ILD 40, CESL 38, and gate spacers 34 are removed. For example, a planarization process, like a CMP, may remove the portions of the layer for the gate electrodes 48, one or more optional conformal layers 46, and gate dielectric layer 44 above the top surfaces of the ILD 40, CESL 38, and gate spacers 34. Each replacement gate structure including the gate electrode 48, one or more optional conformal layers 46, and gate dielectric layer 44 may therefore be formed as illustrated in FIG. 8A-C.

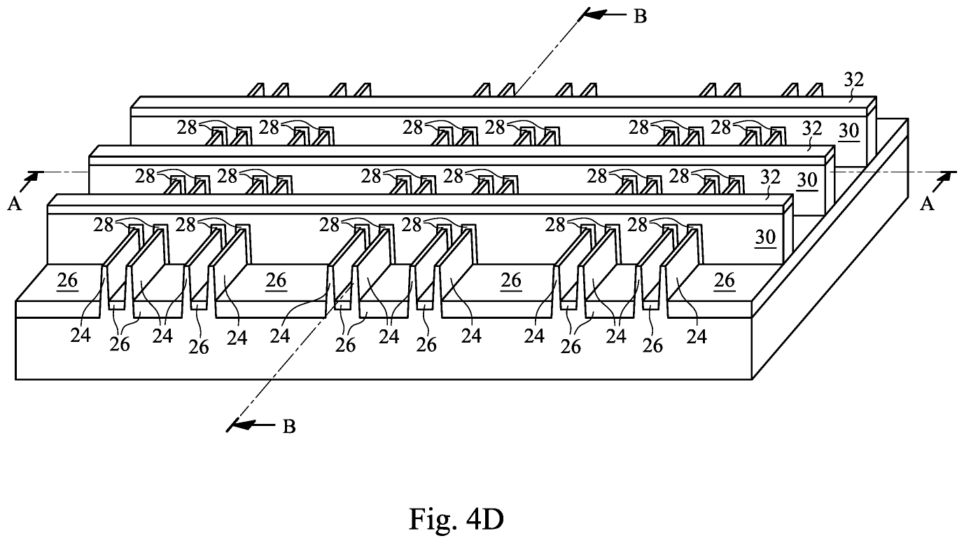

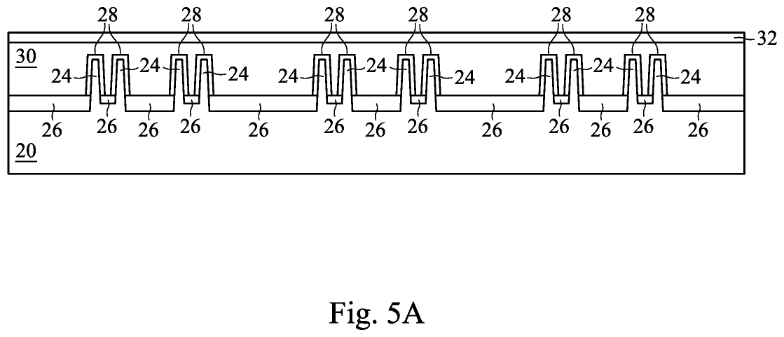

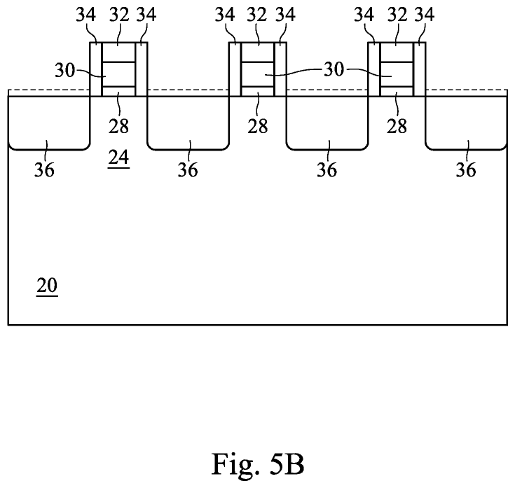

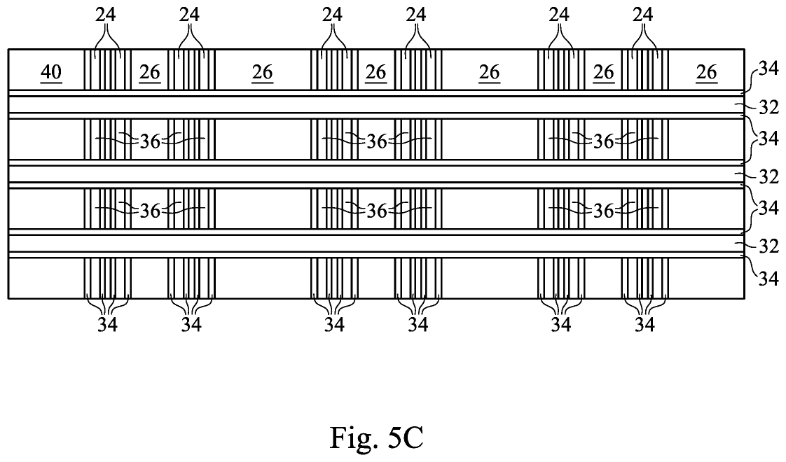

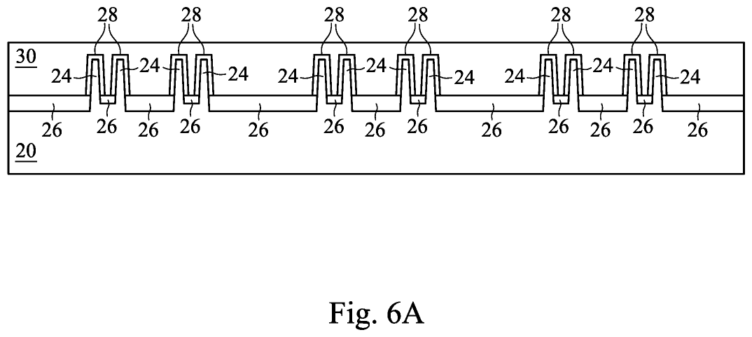

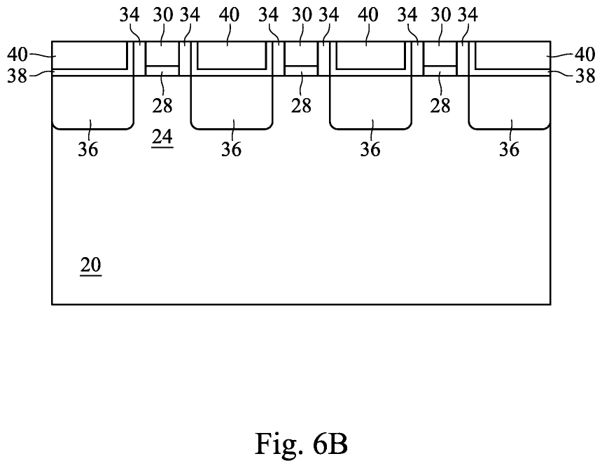

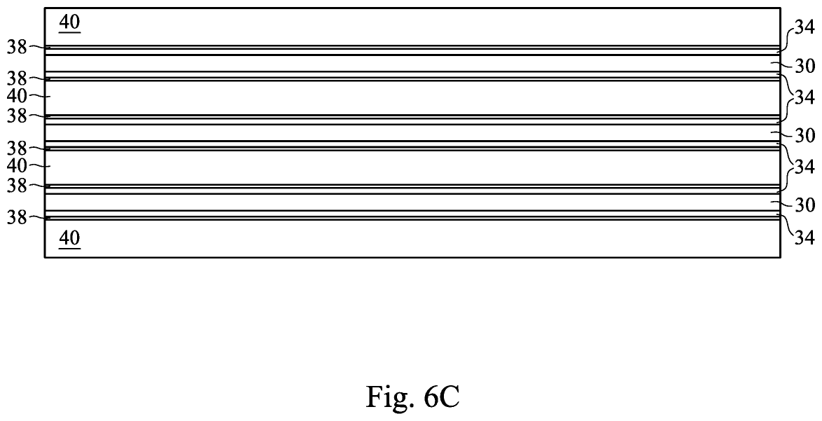

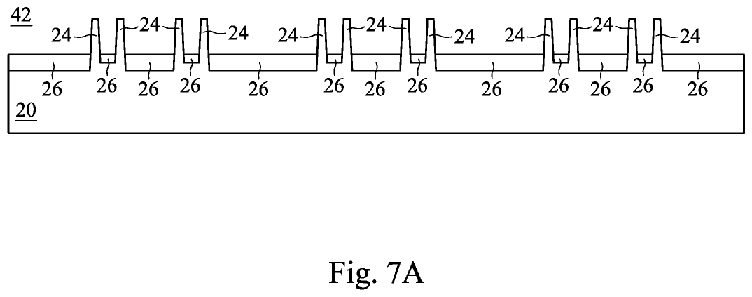

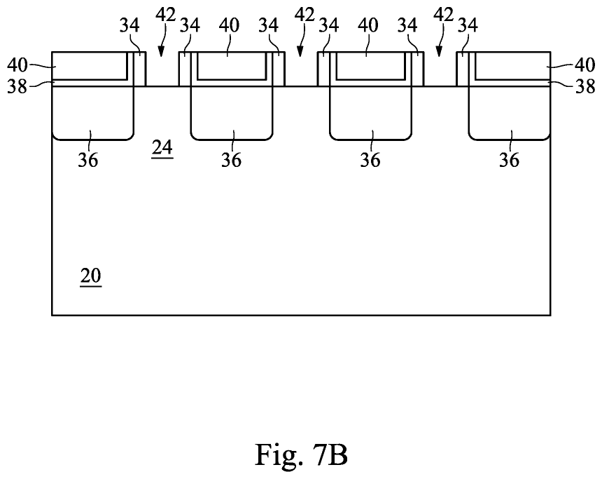

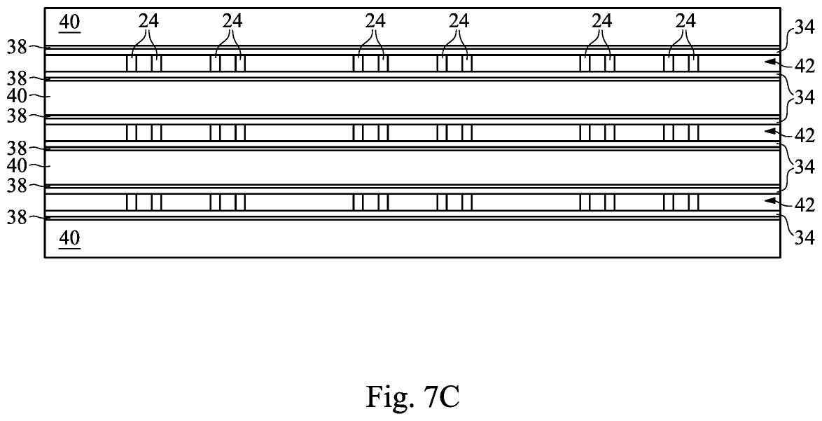

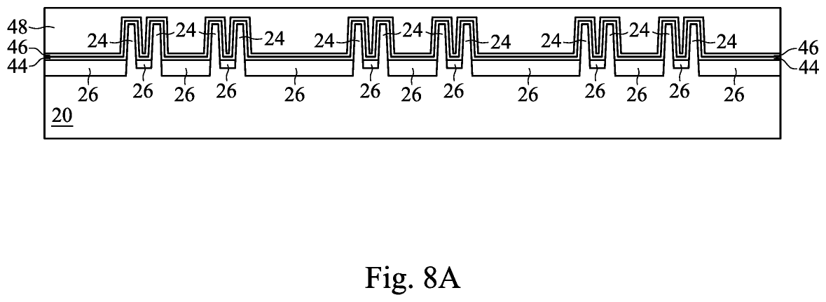

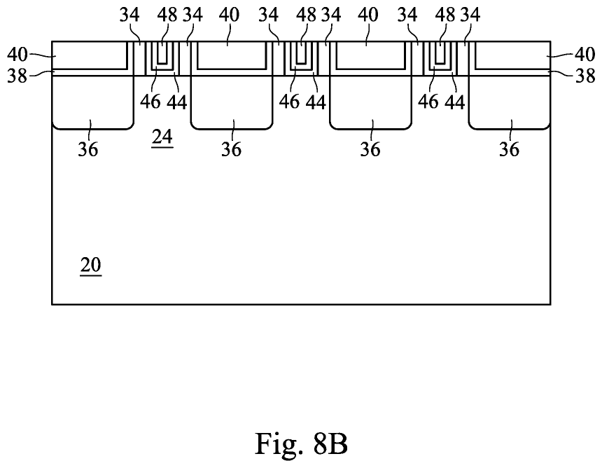

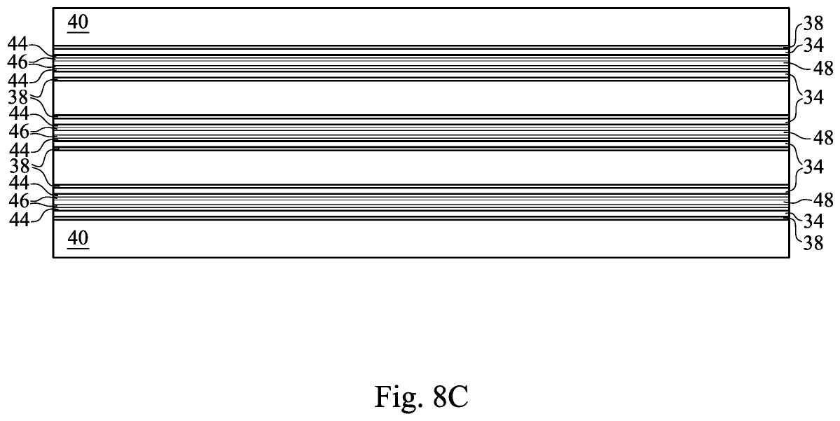

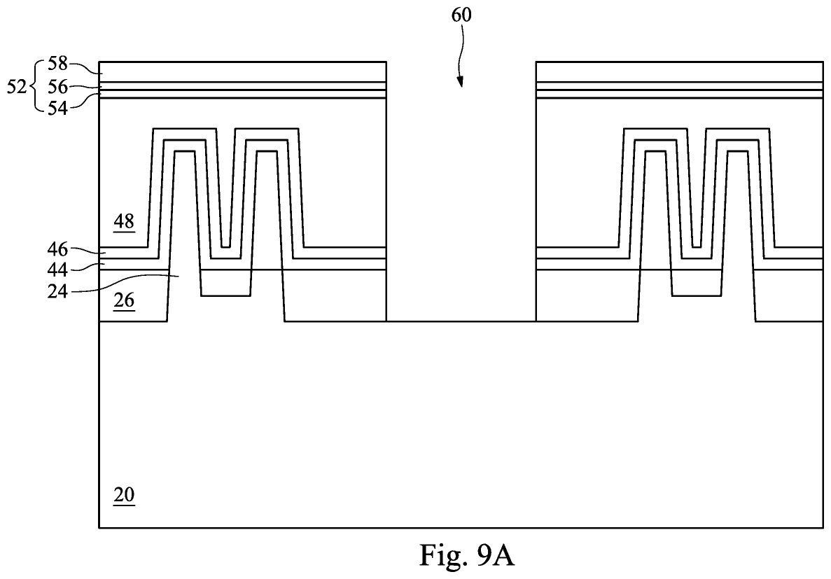

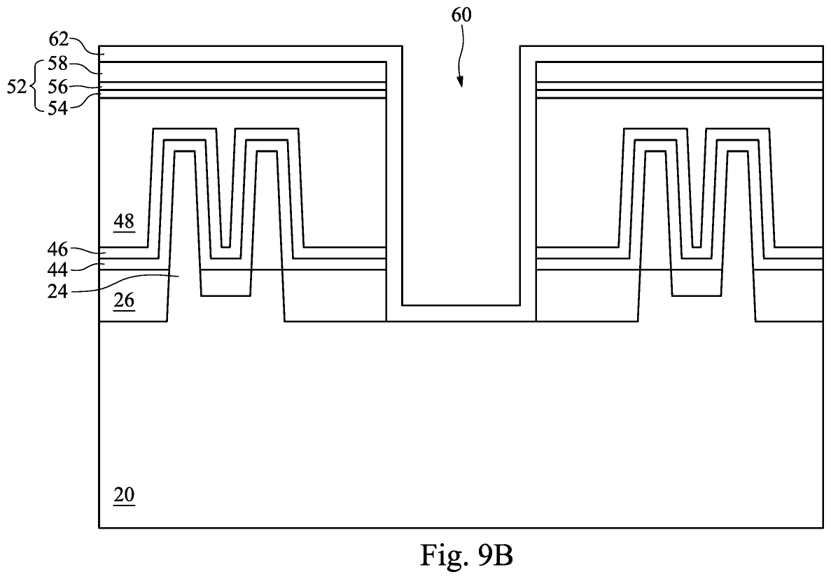

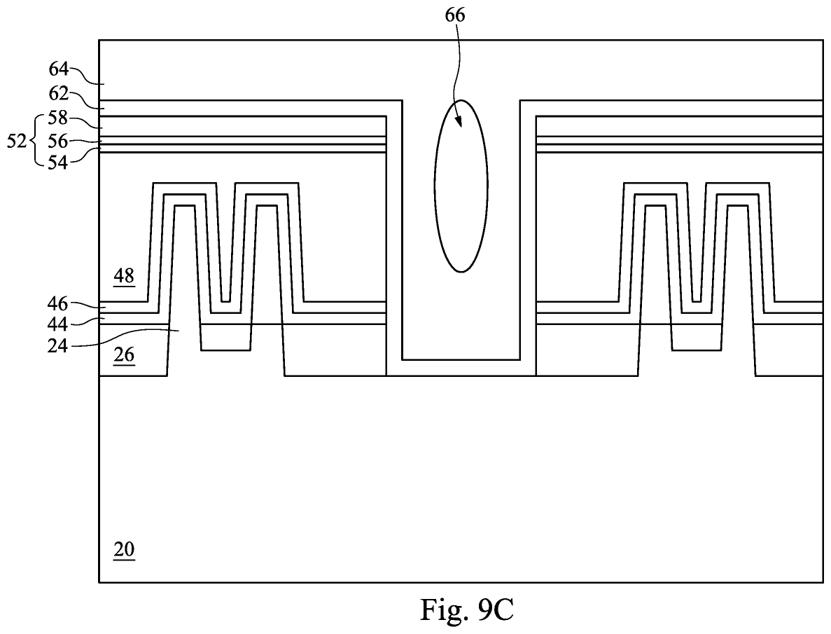

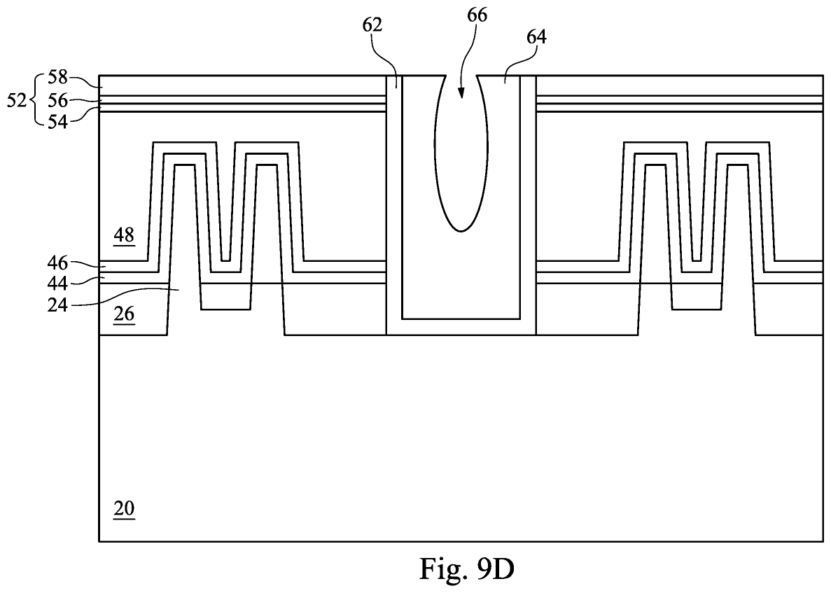

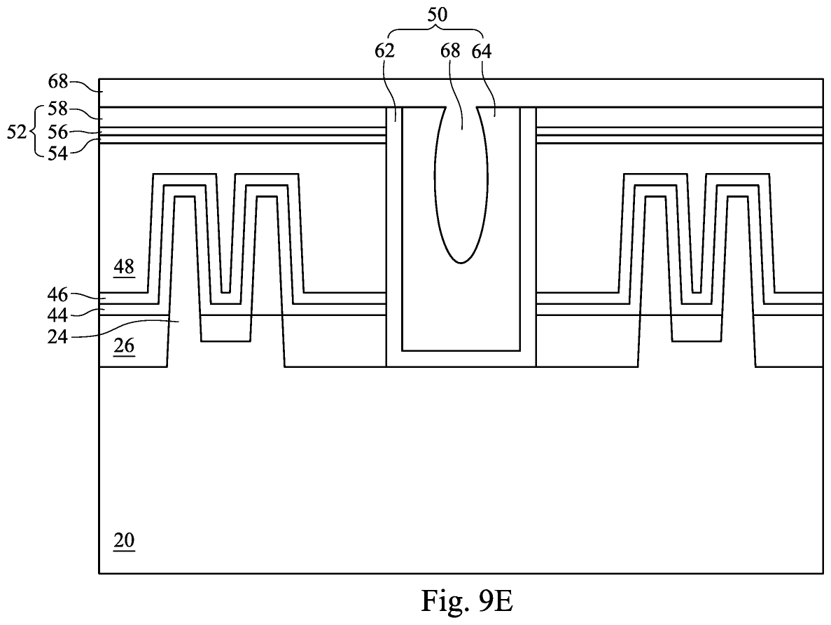

FIGS. 9A-9E are cross-sectional views at various instances of processing corresponding to cross-section A-A in FIG. 4D, in accordance with some embodiments. As shown in FIG. 9A, a mask structure 52 is formed on the gate electrodes 48. The mask structure may be also formed on the ILD 40. The mask structure 52 includes one or more layers 54, 56, 58. In some embodiments, the layer 54 includes SiN, the layer 56 includes amorphous silicon, and the layer 58 includes SiN. The mask structure 52 may include more or less layers. An opening 60 is formed in the mask structure 52 and the replacement gate structure. In some embodiments, the opening 60 is formed in the mask structure 52, the gate electrodes 48, the one or more optional conformal layers 46, the gate dielectric layer 44, and the isolation regions 26. In some embodiments, as shown in FIG. 9A, the opening 60 extends into the semiconductor substrate 20. In some embodiments, the opening 60 does not extend into the semiconductor substrate 20, and the opening 60 exposes a top surface of the semiconductor substrate 20. The opening 60 maybe formed by one or more etch processes.

As shown in FIG. 9B, a liner 62 is formed in the opening 60, such as on the sidewall and the bottom of the opening 60. The liner 62 may include a dielectric material, such as SiN, SiC, SiCN, or other suitable material. The dielectric material of the liner 62 maybe oxygen-free to prevent oxidation of the gate electrodes 48. The liner 62 maybe formed by a conformal process, such as ALD. As a result of having the liner 62, the critical dimension of the opening 60 is reduced, and the aspect ratio of the opening 60 is increased. Next, as shown in FIG. 9C, a dielectric material 64 is formed in the opening 60. The dielectric material 64 maybe a low-k dielectric material having a k value less than about 5. In some embodiments, the dielectric material 64 includes SiO, SiOF, SiOC, Spin-On organic polymeric dielectrics, Spin-On silicon based polymeric dielectrics, or other suitable dielectric material. In some embodiments, the dielectric material 64 includes the same material as the ILD 40. The dielectric material 64 may be formed by any suitable process, such as FCVD. The dielectric material 64 has a low k value, which leads to reduced parasitic capacitance. However, the gapfill capability of the dielectric material 64 is poor in the high aspect ratio opening 60, and a void 66 is formed in the dielectric material 64. In some embodiments, the void 66 has a dimension greater than about 1 nm. The void 66 can lead to electrical short of the subsequently formed conductive contacts.

As shown in FIG. 9D, a planarization process is performed to expose the void 66. Because the void 66 is formed as a result of pinch-off at the entrance of the opening 60, which is defined by the portions of the liner 62 disposed on the mask structure 52, the planarization process, such as a CMP, removes a portion of the dielectric material 64 and a portion of the liner 62 formed on the mask structure 52. If the portion of the liner 62 formed on the mask structure 52 is not removed, the void 66 may not be exposed. In some embodiments, the planarization process may remove a portion of the layer 58 in order to ensure that the void 66 is exposed.

As shown in FIG. 9E, a dielectric material 68 is formed to fill the void 66. The dielectric material 68 may include the same material as the liner 62. In some embodiments, the dielectric material 68 is formed by ALD. The dielectric material 68 has better gapfill capability than the dielectric material 64. Furthermore, the aspect ratio of the void 66 is substantially less than the aspect ratio of the opening 60 after the formation of the liner 62. As a result, the void 66 is filled by the dielectric material 68. The dielectric material 68 has a higher etching resistance compared to the dielectric material 64 during subsequent process of forming contact openings, and the dielectric material 68 can serve as an etch stop layer in the contact openings formation process. Even though the k value of the dielectric material 68 is substantially higher than the k value of the dielectric material 64, the k value of the dielectric material 68 is still relatively low, leading to reduced parasitic capacitance.

Subsequent processes may be performed to remove the portion of the dielectric material 68 formed on the mask structure 52 and to remove the mask structure 52. The removal of the materials may be performed by a planarization process, such as CMP. The portions of the liner 62 and the dielectric materials 64, 68 located in the masks structure 52 maybe also removed. In some embodiments, the mask structure 52 and the portions of the liner 62, the dielectric materials 64, 68 located in the masks structure 52 are not removed. The remaining portions of the liner 62 and the dielectric materials 64, 68 may form a gate cut-fill structure 50. Portions of a replacement gate structure that were integral before the cutting of the replacement gate structure can be made to be electrically isolated sections from each other because of the gate cut-fill structure 50. As a result of the processes described in FIGS. 9A-9E, the gate cut-fill structure 50 includes multiple dielectric materials having an overall low k value, the gate cut-fill structure 50 is seamless or void-free, and the top surface of the gate fill structure 50 includes the liner 62 and the dielectric material 68, which are more etching resistance during the subsequent contact opening process than the dielectric material 64.

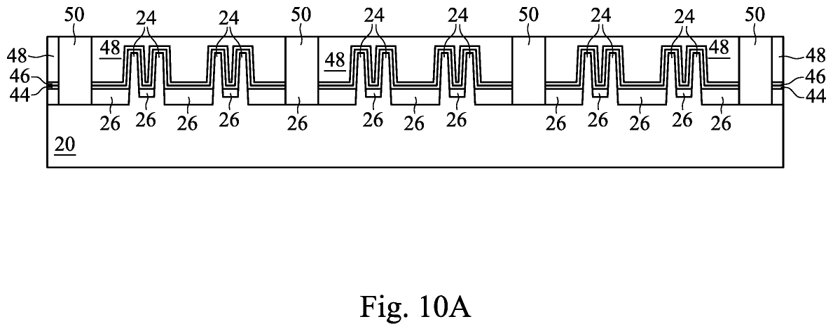

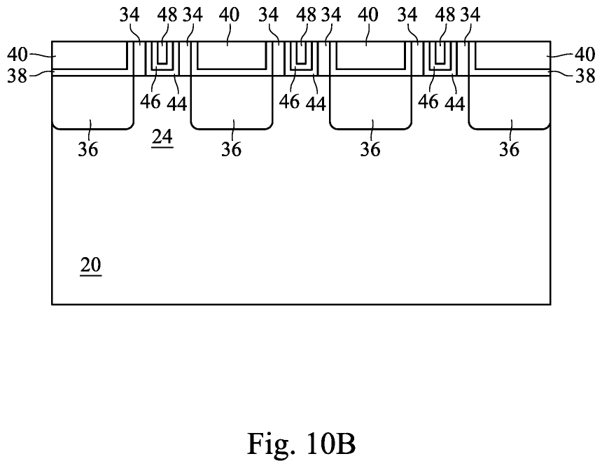

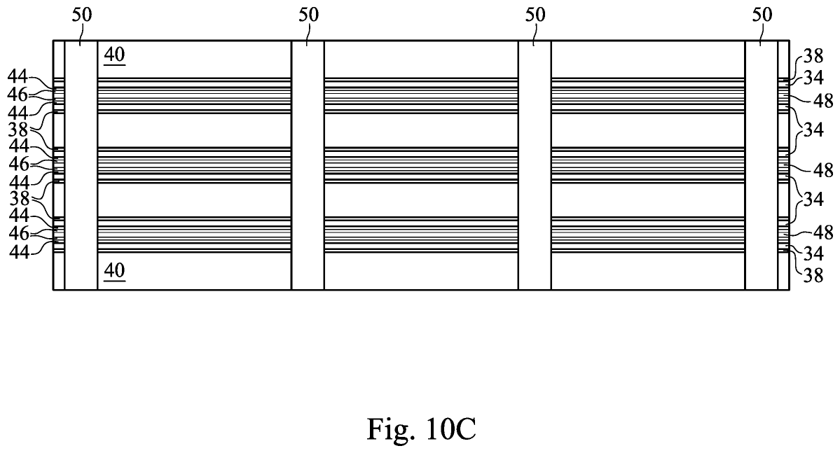

FIGS. 10A-10C are various views of one the intermediate structure at one of intermediate stages in the example process of forming the semiconductor device structure, in accordance with some embodiments. As shown in FIGS. 10A-10C, the gate cut-fill structure 50 separates the gate electrode 48 into multiple electrically isolated portions. The gate cut-fill structure 50 may extend across multiple gate electrodes 48, as shown in FIG. 10C. In some embodiments, the gate cut-fill structure 50 extends across one or more gate electrodes 48.

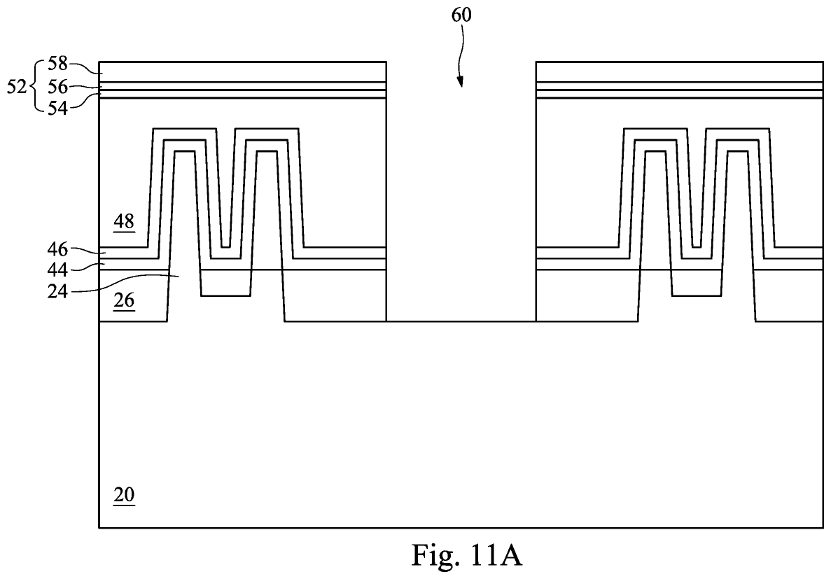

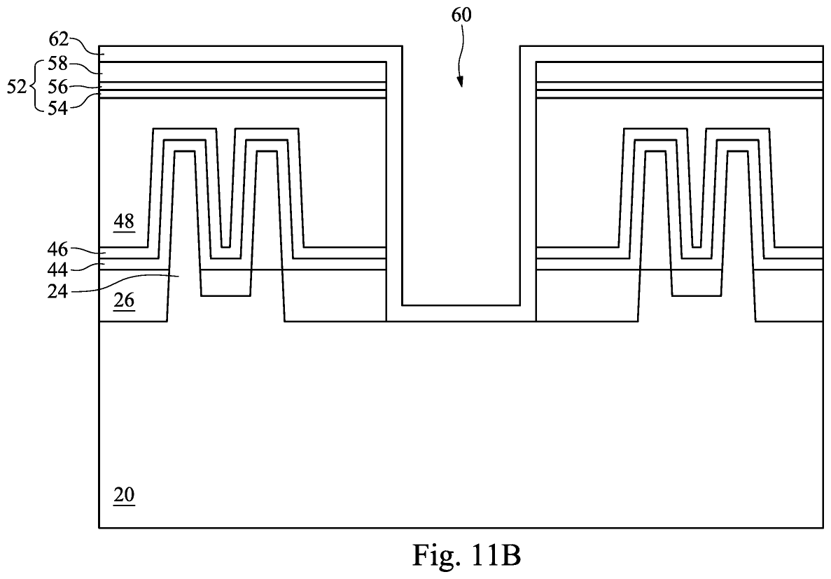

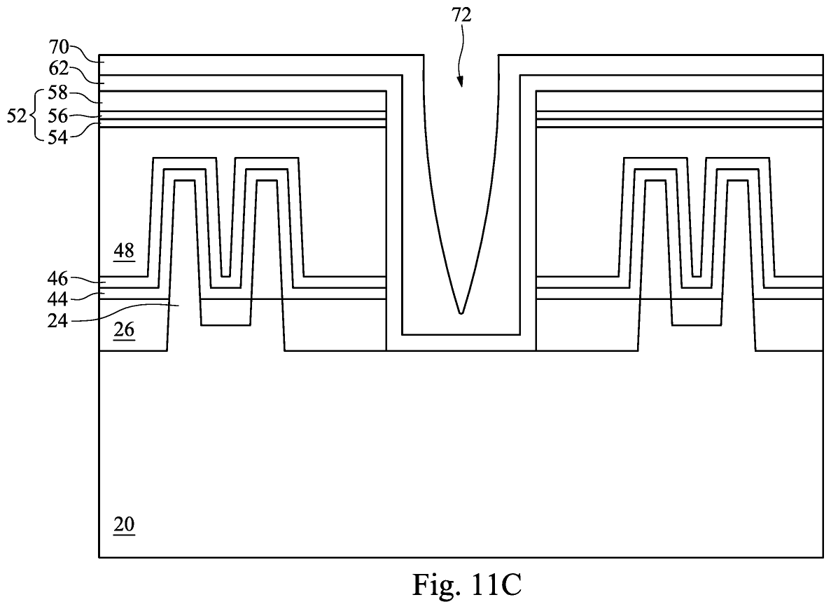

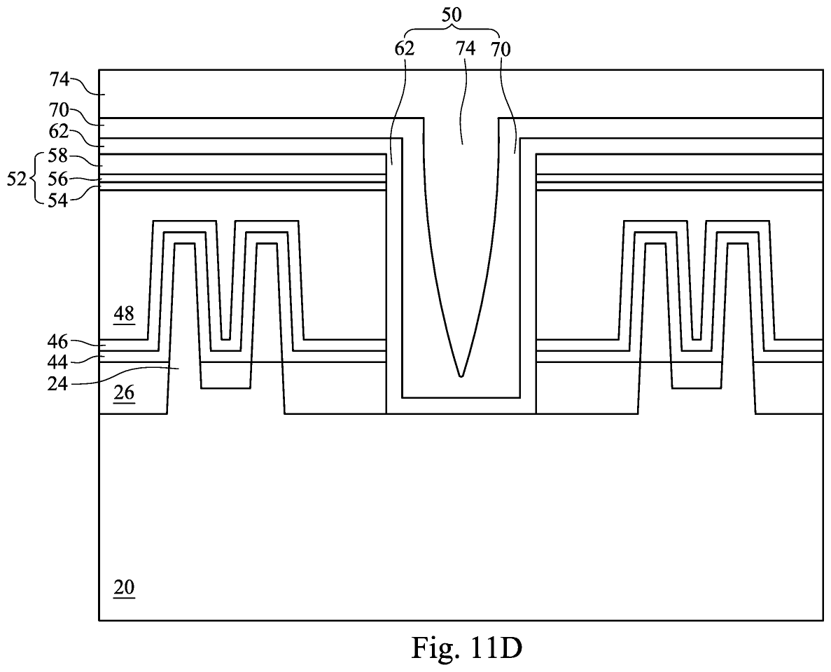

FIGS. 11A-11D are cross-sectional views at various instances of processing corresponding to cross-section A-A in FIG. 4D, in accordance with alternative embodiments. The gate cut-fill structure 50 maybe formed by a different process. As shown in FIG. 11A, the opening 60 is formed to expose a top surface of the semiconductor substrate 20. Next, as shown in FIG. 11B, the liner 62 is formed in the opening 60. In some embodiments, the liner 62 includes SiN and is treated with a plasma including a nitrogen-containing gas, such as N₂ gas, to form a dense nitride layer that prevents oxidation of the gate electrodes 48. The treatment of the liner 62 maybe performed after the deposition of the liner 62 or during the deposition of the liner 62. For example, the liner 62 is formed by an ALD process. The ALD process includes multiple cycles, and each cycle includes forming a monolayer from a first precursor, reacting the monolayer with a second precursor to form a layer, and treating the layer with the plasma. The treatment of the liner 62 by the plasma increases the density of the liner 62, which in turn prevents oxidation of the gate electrodes 48 because the liner 62 is a nitride. The treatment of the liner 62 leaves the liner 62 with-NH terminated surface, which is an inhibitor for adsorption of precursors of silicon oxide.

As shown in FIG. 11C, another liner 70 is formed on the liner 62. In some embodiments, the liner 70 includes the same material as the liner 62, and the liner 70 is not treated. In addition, the liner 70 is formed by an ALD at a lower pressure than the processing pressure for forming the liner 62 to improve the gapfill capability of the liner 70. As a result, no pinch-off occurs during the formation of the liner 70, and an opening 72 is formed, as shown in FIG. 11C.

As shown in FIG. 11D, a dielectric material 74 is formed on the liner 70 filling the opening 72. The dielectric material 74 may include the same material as the dielectric material 64. In some embodiments, the dielectric material 74 includes an oxide, such as silicon oxide. Because the liner 70 is not treated, there are fewer —NH terminated groups on the surface of the liner 70. As a result, the incubation time for the formation of the dielectric material 74, which leads to increased growth per cycle (GPC). In some embodiments, the gapfill capability of the dielectric material 74 is improved by treating the dielectric material 74 with a nitrogen-containing gas or nitrogen-containing plasma during the formation of the dielectric material 74. For example, the dielectric material 74 is formed by an ALD, and the ALD includes multiple cycles. In some embodiments, each cycle includes forming a monolayer from a first precursor, reacting the monolayer with a second precursor to form a layer, such as a silicon oxide layer, and treating the layer with the nitrogen-containing gas or nitrogen-containing plasma. The nitrogen-containing gas may be N₂ gas or other suitable nitrogen-containing gas.

As show in FIG. 11D, the dielectric material 74 has a “V” shaped cross-section, which is due to the “V” shaped cross-section of the opening 72. The shape of the opening 72 is a result of forming the liner 70 at a lower pressure. In other words, the improved gapfill capability of the liner 70 leads to the “V” shaped opening 72, which in turn leads to “V” shaped dielectric material 74.

Subsequent processes may be performed to remove the portion of the liner 62, the portion of the liner 70, and the portion of the dielectric material 74 formed on the mask structure 52 and to remove the mask structure 52. The removal of the materials may be performed by a planarization process, such as CMP. The portions of the liners 62, 70 and the dielectric material 74 located in the masks structure 52 maybe also removed. In some embodiments, the mask structure 52 and the portions of the liners 62, 70 and the dielectric material 74 located in the masks structure 52 are not removed. The remaining portions of the liners 62, 70 and the dielectric material 74 may form the gate cut-fill structure 50. As a result of the processes described in FIGS. 11A-11D, the gate cut-fill structure 50 includes multiple dielectric materials having an overall low k value, which leads to reduced parasitic capacitance. The gate cut-fill structure 50 is seamless or void-free, which leads to reduced risk of electrical short of the subsequently formed conductive contacts.

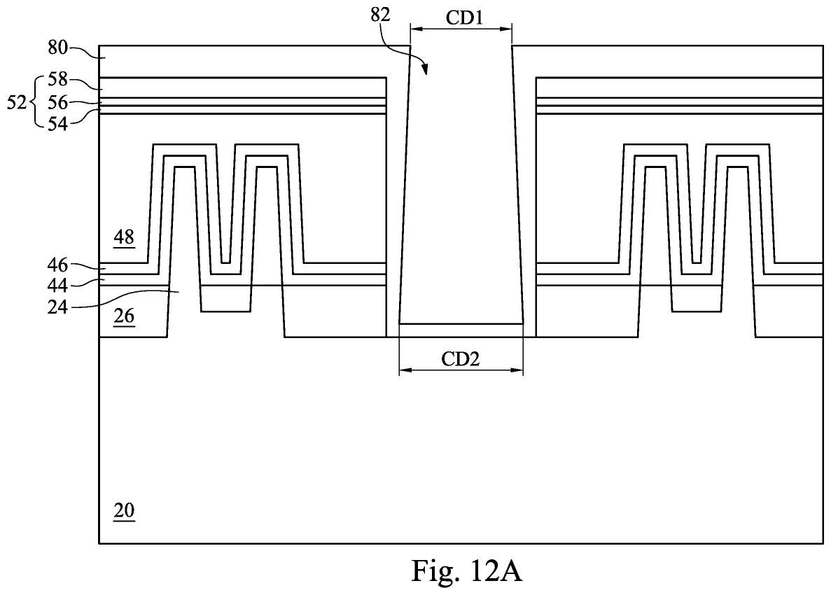

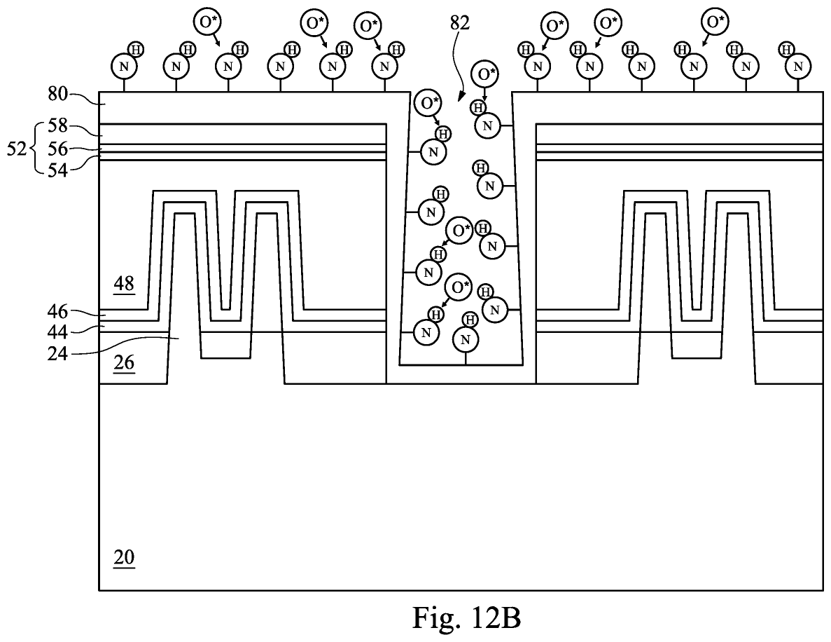

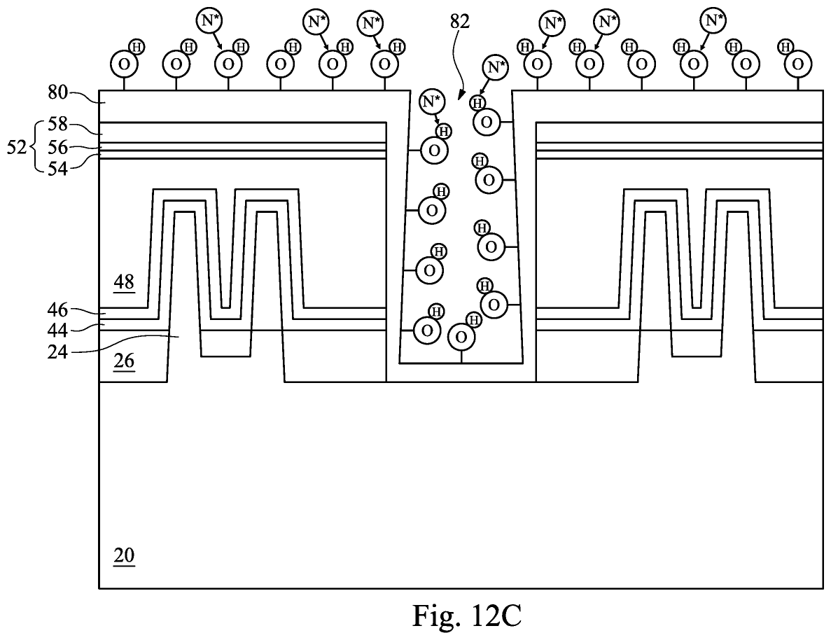

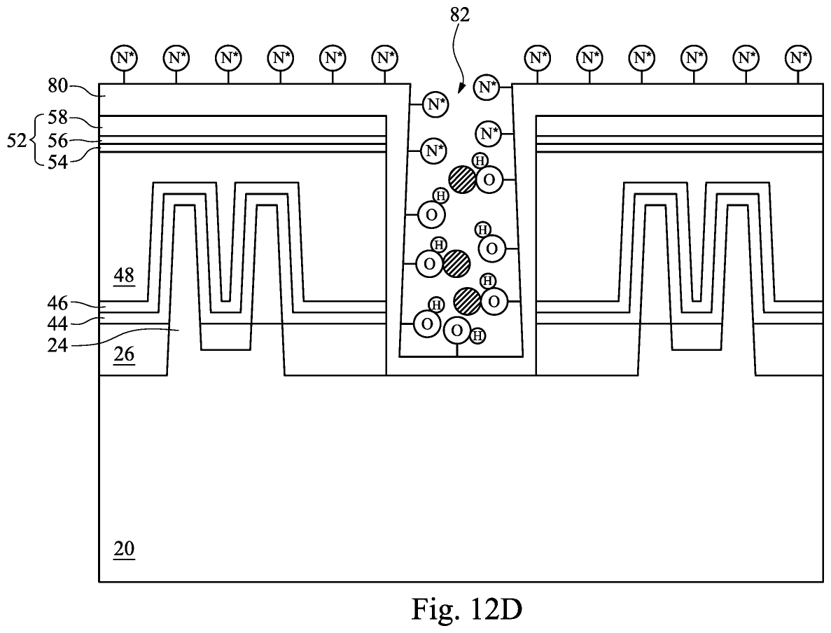

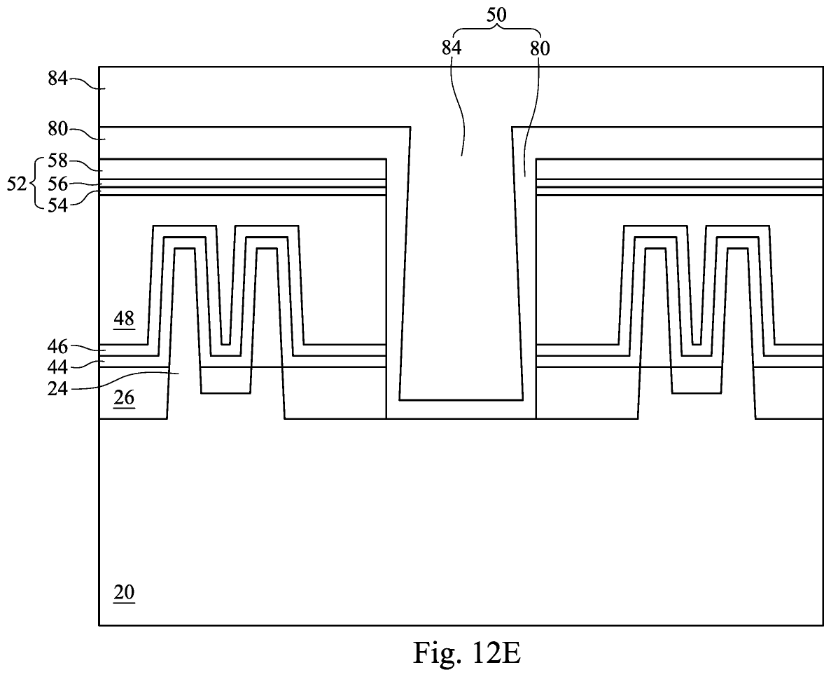

FIGS. 12A-12E are cross-sectional views at various instances of processing corresponding to cross-section A-A in FIG. 4D, in accordance with alternative embodiments. The gate cut-fill structure 50 maybe formed by yet another different process. As shown in FIG. 12A, a liner 80 is formed in the opening 60 (FIG. 11A), and the liner 80 define an opening 82. The liner 80 maybe a nitride layer, such as SiN or SiCN. The liner 80 is formed by plasma enhanced ALD (PEALD), and the liner 80 has decreasing conformality with trench depth. In other words, the thickness of portions of the liner 80 formed on the sidewall of the opening 60 decreases in a direction towards a bottom of the opening 60. As a result, the opening 82 has a first critical dimension CD1 at the entrance than a second critical dimension CD2 at the bottom. The overhang cross-section profile of the liner 80 can lead to the formation of void or seam in a subsequently formed dielectric material 84. In order to avoid the formation of the void or seam in the dielectric material 84, plasma treatments are performed on the liner 80.

As shown in FIG. 12B, a first plasma treatment is performed on the liner 80. The first plasma treatment includes exposing the liner 80 to an oxygen plasma. For example, an oxygen-containing gas, such as O₂ gas, is utilized in forming the oxygen plasma. The oxygen plasma converts the —NH groups at the surface of the liner 80 to —OH groups, as shown in FIG. 12B. In some embodiments, the first plasma treatment is performed for a first time duration that substantially the entire surface of the liner 80 is converted to —OH groups.

Next, as shown in FIG. 12C, a second plasma treatment is performed on the liner 80. The second plasma treatment includes exposing the treated liner 80 to a nitrogen plasma. For example, a nitrogen-containing gas, such as N₂ gas, is utilized in forming the nitrogen plasma. The nitrogen plasma converts the —OH groups located on the surface of the liner 80 at the entrance of the opening 82 to —N groups, as shown in FIG. 12C. The —OH groups located on the remaining surface of the liner 80 are not affected. In other words, the portion of the surface of the liner 80 located at the top portion of the opening 82 is converted to —N groups, while the portion of the surface of the liner 80 located at the bottom portion of the opening 82 is substantially unaffected. In some embodiments, the second plasma treatment is performed for a second time duration substantially less than the first time duration, in order to ensure that the —OH groups located at the bottom portion of the liner 80 are not affected by the second plasma treatment. In some embodiments, the first time duration is about 3 times longer than the second time duration. In some embodiments, in addition to shorter time duration, the second plasma treatment may utilize lower processing pressure and higher plasma power to ensure that the —OH groups located at the bottom portion of the liner 80 are not affected by the second plasma treatment.

As shown in FIG. 12D, a precursor for forming the dielectric material 84 is attached to the —OH groups located at the bottom portion of the opening 82, while the —N groups located at the top portion of the opening 82 inhibits the adsorption of the precursor. In some embodiments, the dielectric material 84 is an oxide, such as silicon oxide, and the precursor is a silicon-containing or an oxygen-containing precursor. As a result of the plasma treatments, the dielectric material 84 forms faster at the bottom portion of the liner 80 than at the top portion of the liner 80. As a result, the opening 82 is filled with the dielectric material 84 without a void or seam, as shown in FIG. 12E. In some embodiments, the dielectric material 84 includes the same material as the dielectric material 74. In some embodiments, the dielectric material 84 is formed by PEALD.

Subsequent processes may be performed to remove the portion of the liner 80 and the portion of the dielectric material 84 formed on the mask structure 52 and to remove the mask structure 52. The removal of the materials may be performed by a planarization process, such as CMP. The portions of the liner 80 and the dielectric material 84 located in the masks structure 52 maybe also removed. In some embodiments, the mask structure 52 and the portions of the liner 80 and the dielectric material 84 located in the masks structure 52 are not removed. The remaining portions of the liner 80 and the dielectric material 84 may form the gate cut-fill structure 50. As a result of the processes described in FIGS. 12A-12D, the gate cut-fill structure 50 includes multiple dielectric materials having an overall low k value, which leads to reduced parasitic capacitance. The gate cut-fill structure 50 is seamless or void-free, which leads to reduced risk of electrical short of the subsequently formed conductive contacts.

The present disclosure provides a method for forming a semiconductor device structure. The method includes forming an opening 60 in a gate electrode 48, forming a first liner 62 in the opening 60, forming a dielectric material 64 on the liner 62 in the opening 60, and a void 66 is formed in the dielectric material 64. A portion of the dielectric material 64 is removed to expose the void 66, and another dielectric material 68 is formed in the void 66. The liner 62 and the dielectric materials 64, 68 form the gate cut-fill structure 50. Some embodiments may achieve advantages. For example, gate cut-fill structure 50 includes multiple dielectric materials having an overall low k value, the gate cut-fill structure 50 is seamless or void-free, and the top surface of the gate fill structure 50 includes the liner 62 and the dielectric material 68, which are more etching resistance during the subsequent contact opening process than the dielectric material 64.

An embodiment is a semiconductor device structure. The structure includes a gate electrode disposed over a semiconductor substrate and a gate cut-fill structure disposed in the gate electrode to separate the gate electrode into two portions. The gate cut-fill structure includes a first liner, a second liner disposed on the first liner, and a dielectric material disposed on the second liner. The dielectric material has a “V” shaped cross-section.

Another embodiment is a method. The method includes forming a plurality of fins from a semiconductor substrate, forming isolation regions around each fin of the plurality of fins, depositing a gate electrode over the plurality of fins, forming an opening in the gate electrode, depositing a first liner in the opening, and depositing a first dielectric material on the liner. A void is formed in the first dielectric material. The method further includes removing a portion of the first dielectric material to expose the void and depositing a second dielectric material in the void.

A further embodiment is a method. The method includes forming a plurality of fins from a semiconductor substrate, forming isolation regions around each fin of the plurality of fins, depositing a gate electrode over the plurality of fins, forming an opening in the gate electrode, depositing a liner in the opening, performing a first plasma treatment on the liner, and performing a second plasma treatment on the liner. Different groups are formed on a surface of the liner. The method further includes depositing a seamless dielectric material on the liner, and the opening is filled with the liner and the dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a gate electrode disposed over a semiconductor substrate; and
a gate cut-fill structure disposed in the gate electrode to separate the gate electrode into two portions, the gate cut-fill structure comprises:
a first liner;
a second liner disposed on the first liner; and
a dielectric material disposed on the second liner, wherein the dielectric material has a “V” shaped cross-section.

2. The semiconductor device structure of claim 1, further comprising one or more fins, wherein the gate electrode is disposed over the one or more fins.

3. The semiconductor device structure of claim 2, further comprising a gate dielectric layer disposed over the one or more fins, wherein the gate electrode is disposed over the gate dielectric layer.

4. The semiconductor device structure of claim 3, further comprising one or more conformal layers disposed over the gate dielectric layer, wherein the gate electrode is disposed over the one or more conformal layers.

5. The semiconductor device structure of claim 1, wherein the first liner and the dielectric material comprise different materials.

6. The semiconductor device structure of claim 5, wherein the first liner and the second liner comprise a same material, and a surface of the first liner and a surface of the second liner include different groups.

7. A method, comprising:
forming a plurality of fins from a semiconductor substrate;
forming isolation regions around each fin of the plurality of fins;
depositing a gate electrode over the plurality of fins;
forming an opening in the gate electrode;
depositing a first liner in the opening;
depositing a first dielectric material on the liner, wherein a void is formed in the first dielectric material;
removing a portion of the first dielectric material to expose the void; and
depositing a second dielectric material in the void.

8. The method of claim 7, wherein the first liner is deposited by atomic layer deposition.

9. The method of claim 8, wherein first dielectric material is deposited by flowable chemical vapor deposition.

10. The method of claim 9, wherein the second dielectric material is deposited by atomic layer deposition.

11. The method of claim 7, further comprising forming a mask structure over the gate electrode, wherein the opening is formed in the mask structure.

12. The method of claim 11, wherein the mask structure comprises one or more layers.

13. The method of claim 12, wherein the one or more layers include a first SiN layer, a second SiN layer, and a silicon layer disposed between the first and second SiN layers.

14. The method of claim 7, further comprising performing a first planarization process to expose the gate electrode.

15. The method of claim 7, wherein the removing the portion of the first dielectric layer is performed by a second planarization process.

16. A method, comprising:
forming a plurality of fins from a semiconductor substrate;
forming isolation regions around each fin of the plurality of fins;
depositing a gate electrode over the plurality of fins;
forming an opening in the gate electrode;
depositing a liner in the opening;
performing a first plasma treatment on the liner;
performing a second plasma treatment on the liner, wherein different groups are formed on a surface of the liner; and
depositing a seamless dielectric material on the liner, wherein the opening is filled with the liner and the dielectric material.

17. The method of claim 16, wherein the first plasma treatment comprises exposing the liner to an oxygen plasma.

18. The method of claim 17, wherein the second plasma treatment comprises exposing the liner to a nitrogen plasma.

19. The method of claim 18, wherein the different groups comprise —OH groups and —N groups.

20. The method of claim 18, wherein the second plasma treatment is performed for a time duration substantially less than a time duration of the first plasma treatment.
